(19) United States
(12) Patent Application Publication
(10) Pub. No.: US 2012/0025930 A1
(43) Pub. Date: Feb. 2, 2012

(54) PROGRAMMABLE ANTIFUSE MATRIX FOR MODULE DECOUPLING

(75) Inventors: DON A. GILLILAND, ROCHESTER, MN (US); DENNIS J. WURTH, ROCHESTER, MN (US)

(73) Assignee: INTERNATIONAL BUSINESS MACHINES CORPORATION, ARMONK, NY (US)

(21) Appl. No.: 12/847,059

(22) Filed: Jul. 30, 2010

(51) Int. Cl. H03H 7/00

(52) U.S. Cl. 333/182

(57) ABSTRACT

An adapter couples a module to a circuit board. The adapter comprises a decoupling capacitor, which has a first capacitor plate and a second capacitor plate separated by an insulating dielectric, located within the adapter. A voltage pin and a ground pin within the adapter traverse through the decoupling capacitor in order to make voltage and ground connections between the module and the circuit board. A first fusible ring, which is adjacent to the first capacitor plate, encircles the voltage pin, and a second fusible ring, which is adjacent to the second capacitor plate, encircles the ground pin. When the first and second fusible rings are fused to their respective capacitor plates, the decoupling capacitor provides the module with decoupling capacitance protection from stray alternating current voltage, and also provides the module with power/ground sources to compensate for current/ground spikes.

### BACKGROUND

The present disclosure relates to the field of computers, and specifically to modules mounted on circuit boards. Still more particularly, the present disclosure relates to mounting modules to circuit boards using module adapters.

### BRIEF SUMMARY

In one embodiment of the present disclosure, an adapter couples a module to a circuit board. The adapter comprises a decoupling capacitor, which has a first capacitor plate and a second capacitor plate separated by an insulating dielectric, located within the adapter. A voltage pin and a ground pin within the adapter traverse through the decoupling capacitor in order to make voltage and ground connections between the module and the circuit board. A first fusible ring, which is adjacent to the first capacitor plate, encircles the voltage pin, and a second fusible ring, which is adjacent to the second capacitor plate, encircles the ground pin. When the first and second fusible rings are fused to their respective capacitor plates, the decoupling capacitor provides the module with decoupling capacitance protection.

In one embodiment of the present disclosure, a computer system comprises a circuit board, a module, and an adapter that couples the module to the circuit board. The adapter comprises a decoupling capacitor, which has a first capacitor plate and a second capacitor plate separated by an insulating dielectric, located within the adapter. A voltage pin and a ground pin within the adapter traverse through the decoupling capacitor in order to make voltage and ground connections between the module and the circuit board. A first fusible ring, which is adjacent to the first capacitor plate, encircles the voltage pin, and a second fusible ring, which is adjacent to the second capacitor plate, encircles the ground pin. When the first and second fusible rings are fused to their respective capacitor plates, the decoupling capacitor provides the module with decoupling capacitance protection.

### BRIEF DESCRIPTION OF THE SEVERAL VIEWS OF THE DRAWINGS

FIG. 1 depicts an exemplary ball grid array (BGA) adapter coupling a module to a circuit board;

FIG. 2 depicts a BGA of solder on a face of a BGA module, BGA adapter, or other BGA component;

FIG. 3 illustrates additional detail for two pins in the BGA adapter shown in FIG. 1;

FIG. 4 illustrates a non-conducting substrate in which an antifuse used in one embodiment of the present disclosure has not been grown;

FIG. 5 depicts a conducting antifuse that has been grown for use in one embodiment of the present disclosure;

FIG. 6 illustrates an oblique view of a voltage pin in the BGA adapter traversing through two decoupling capacitors;

FIG. 7 depicts additional detail of FIG. 3 in a cross-sectional view;

FIG. 8 illustrates additional detail of an antifuse without a collar;

FIG. 9 depicts a schematic of FIGS. 3 and 7; and

FIG. 10 depicts a schematic of an alternate embodiment in which different voltages are decoupled by the capacitor described herein.

### DETAILED DESCRIPTION

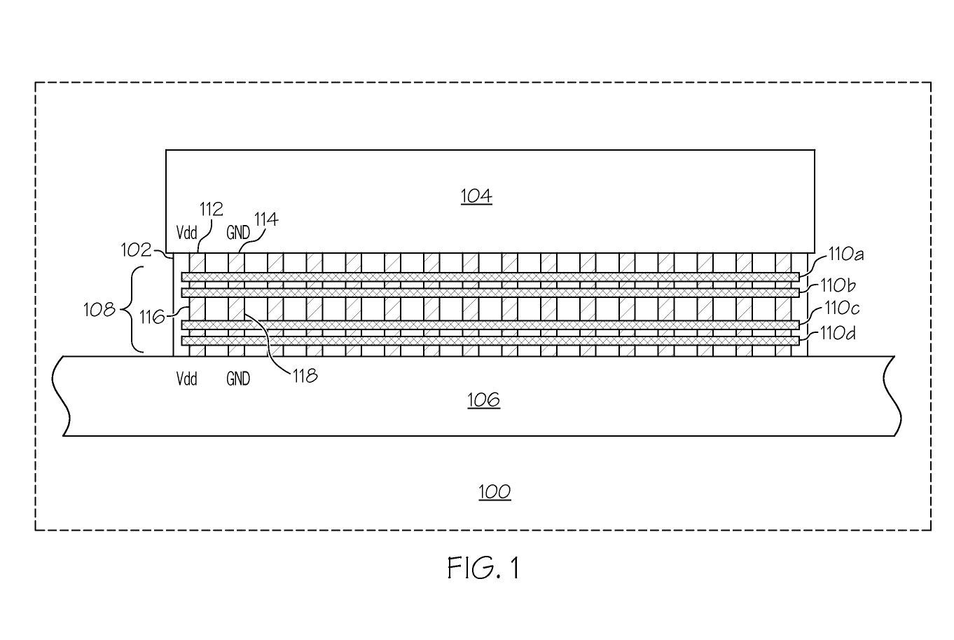

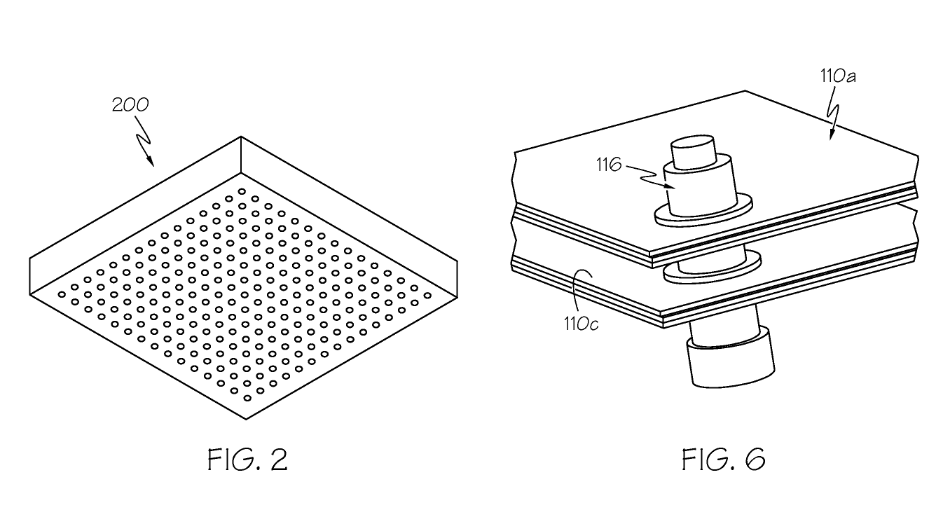

With reference now to FIG. 1, a cross sectional view of an exemplary ball grid array (BGA) adapter 102 is depicted as coupling a module 104 (also shown in a cross-sectional view) to a circuit board 106 (also shown in a cross-sectional view). In one embodiment, the BGA adapter 102, module 104, and circuit board 106 are components of a computer system 100, such as a server, a personal computer, a laptop computer, or any other electronic device that utilizes circuit boards. As the name suggests, in one embodiment BGA adapter 102 utilizes a ball grid array such as BGA array 200 shown in FIG. 2. A BGA system utilizes an array of meltable/fusible balls of solder that are stuck to the bottom of a BGA module, such as module 104 and/or BGA adapter 102. Situated on top of the circuit board 106 are copper pads. By heating the BGA of solder on a BGA module, the solder melts and fuses with the copper pads on top of the circuit board. However, the present disclosure utilizes BGA adapter 102 positioned between the module 104 and the circuit board 106. As such, the meltable/fusible balls of solder are on the bottom of the module 104 as well as the bottom of the BGA adapter 102, such that the meltable/fusible balls of solder on the bottom of the module 104 fuse to copper pads (not shown) on the top of the BGA adapter 102. Similarly, an array of meltable/fusible balls of solder on the bottom of the BGA adapter 102 fuses with copper pads (also not shown) on the top of the circuit board 106. While the present disclosure is described in terms of a BGA system, in one embodiment the features described herein are also applicable to other mounting systems, including pin grid arrays (PGAs), perimeter pin connectors, wire-wrap systems, etc.

Returning to FIG. 1, within BGA adapter 102 is a matrix of pins 108, which connects the module 104 to the circuit board 106 via the balls of solder and copper pads described above. These pins pass through one or more pairs of capacitor plates, depicted as first capacitor plate 110a, second capacitor plate 110b, third capacitor plate 110c, and fourth capacitor plate 110d. As depicted, when separated by an insulating dielectric, first capacitor plate 110a and second capacitor plate 110b create a first capacitor, while third capacitor plate 110c and fourth capacitor plate 110d create a second capacitor, in order to provide decoupling capacitance properties to BGA adapter 102.

A decoupling capacitor is a capacitor used to decouple the module 104 from the circuit board 106. Noise, from the circuit board 106, caused by other circuit elements (not shown) is shunted through the decoupling capacitor, reducing the effect that this noise has on the module 104. Similarly, noise from the module 104 is prevented from reaching the circuit board 106. This noise is most often from stray alternating current (AC) in the system that has become superimposed on a direct current (DC) line. The decoupling capacitor also “smoothes out” voltage and ground supplies, by providing a transient supply of DC current from one plate while having a clean (uncharged) ground plate on the other plate of the capacitor. That is, if module 104 draws a current spike, resulting in a drop in the voltage Vdd, Vdd will try to decrease while Gnd tries to increase. The decoupling capacitors described herein provide transient supplies of DC current and clean ground, and are able to respond to events at frequencies from a few hundred kHz to several MHz. As described herein, BGA adapter 102 provides such decoupling capacitance to module 104. This decoupling capacitance is created, as described in greater detail herein, by fusing a voltage connector 112 in the module 104 to first capacitor plate 110a and/or third capacitor plate 110c, and fusing second capacitor plate 110b and/or fourth capacitor plate 110d to the ground connector 114. Note that a voltage source Vdd from the circuit board 106 is coupled to the voltage connector 112 via a voltage pin 116, while the ground Gnd from the circuit board 106 is coupled to the ground connector 114 via a ground pin 118.

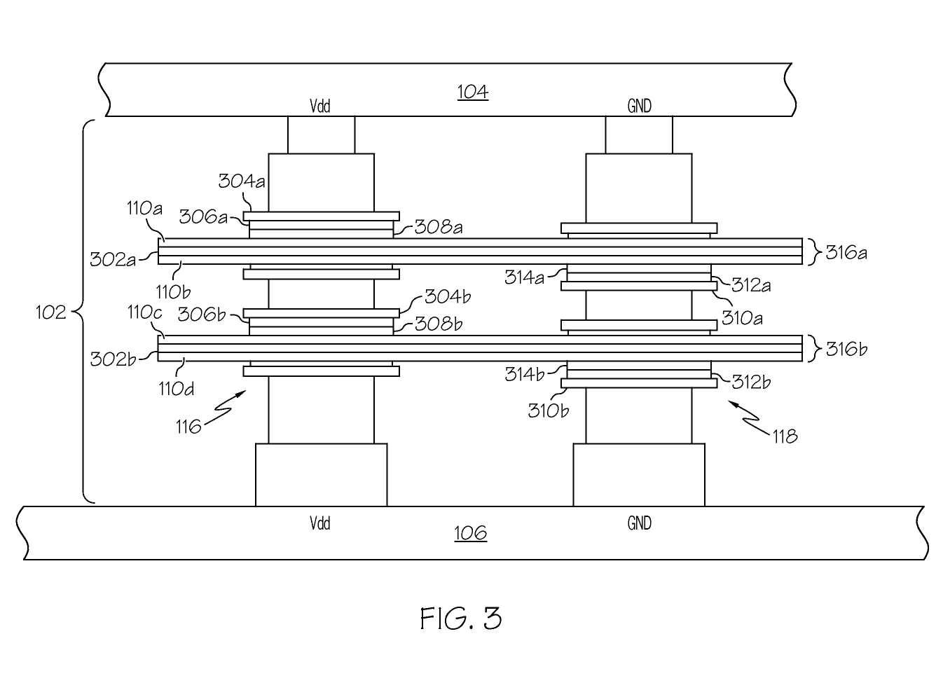

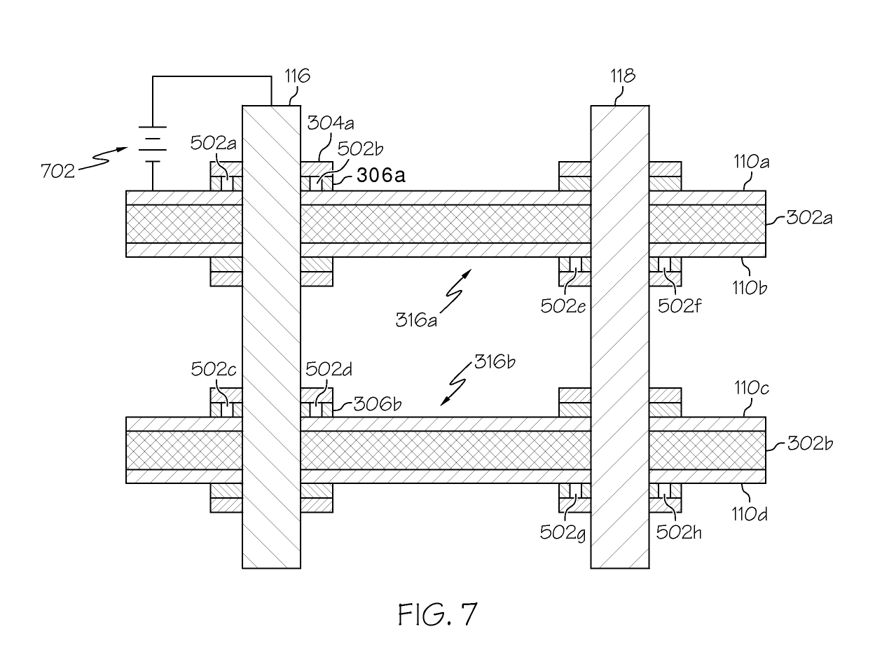

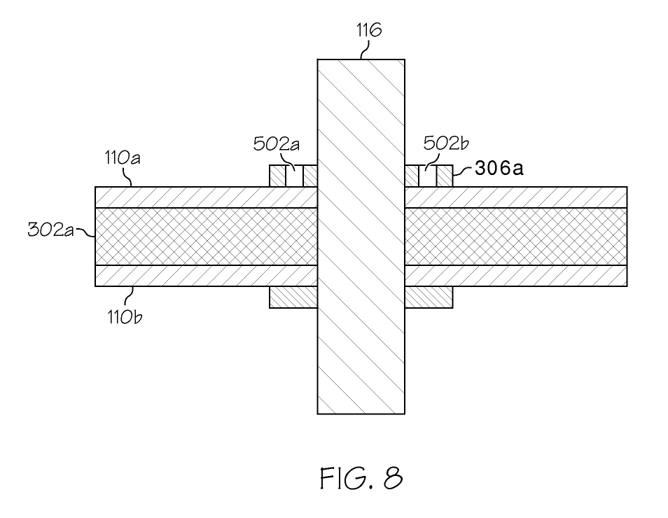

With reference now to FIG. 3, additional detail is presented for structures surrounding the voltage pin 116 and the ground pin 118 shown in FIG. 1. As depicted, voltage pin 116 and ground pin 118 pass through two capacitors, 316a and 316b, located within the BGA adapter 102. Each capacitor is made up of capacitor plates and an insulating dielectric. For example, first capacitor plate 110a, second capacitor plate 110b, and insulating dielectric 302a make up a first decoupling capacitor 316a, while third capacitor plate 110c, fourth capacitor plate 110d, and insulating dielectric 302b make up a second decoupling capacitor 316b. In another embodiment, there is only one capacitor 316 located within the BGA adapter 102. However, having two capacitors 316a-b increases overall capacitor capacity, and thus increases decoupling capacitance. Surrounding voltage pin 116 are collars 304a-b and, adjacent to collars 304a-b, amorphous silicon rings 306a-b. By applying programmable voltage across the amorphous silicon ring 306a, a fusion area 308a (a fusion area that utilizes antifuses 502 as described below in FIGS. 5 and 7) couples the voltage pin 116 to the first capacitor plate 110a (via amorphous silicon ring 306a), while the second capacitor plate 110b remains uncoupled to the voltage pin 116. As depicted in FIG. 3, third capacitor plate 110c can optionally be coupled to the voltage pin 116 via fusion area 308b. If third capacitor plate 110c is not initially coupled to voltage pin 116, fusion area 308b can be programmed for future use. The second antifuse, if and when grown, doubles the amount of decoupling capacitance transient DC current available to voltage pin 116 by making available the decoupling capacitance transient DC current from both first decoupling capacitor 316a and second decoupling capacitor 316b (i.e., connecting decoupling capacitors 316a and 316b in parallel as depicted in FIG. 8). This parallel configuration is achieved by coupling one “side” of voltage pin 116 to the first decoupling capacitor 316a, while coupling the other “side” of voltage pin 116 to the second decoupling capacitor 316b. These two “sides” can be conceptually viewed as if the voltage pin 116 is functionally split down the middle longitudinally.

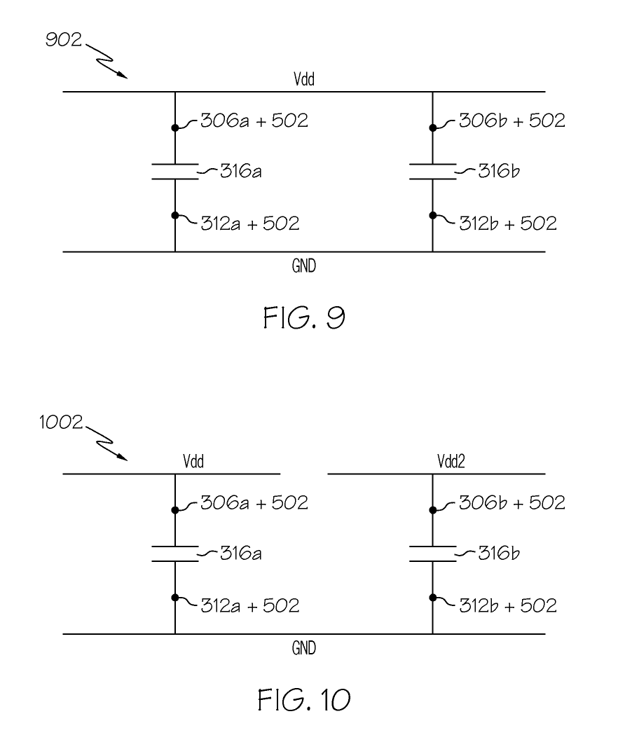

Thus, as depicted in FIG. 3, capacitor 316a has the Vdd voltage pin 116 connected to capacitor plate 110a by fusion area 308a (which utilizes antifuse 502a shown below in FIG. 5). Capacitor 316a has capacitor plate 110b connected to Gnd pin 118 by fusion area 314a. Similarly, capacitor 316b may have Vdd voltage pin 116 connected to capacitor plate 110c via fusion area 308b, and capacitor plate 110d can be antifused/connected to Gnd pin 118 via fusion area 314b. A set of ground pin collars 310a-b also secure the amorphous silicon rings 312a-b in a manner similar to how collars 304a-b secure amorphous silicon rings 306a-b. As described below, FIG. 9 depicts capacitors 316a and 316b and fusion areas (using amorphous silicon rings 306a-b and 312a-b and antifuses 502) needed to connect the Vdd voltage pin and the Gnd ground pin across both capacitor 316a and 316b.

Note that capacitor 316a is positioned in close proximity to module 104, such that any line impedance in the voltage pin 116 between the module 104 and capacitor 316a is kept to a minimum. Note also that capacitor 316b is positioned in close proximity to circuit board 106, such that any line impedance in the ground pin 118 between the circuit board 106 and capacitor 316b is dept to a minimum.

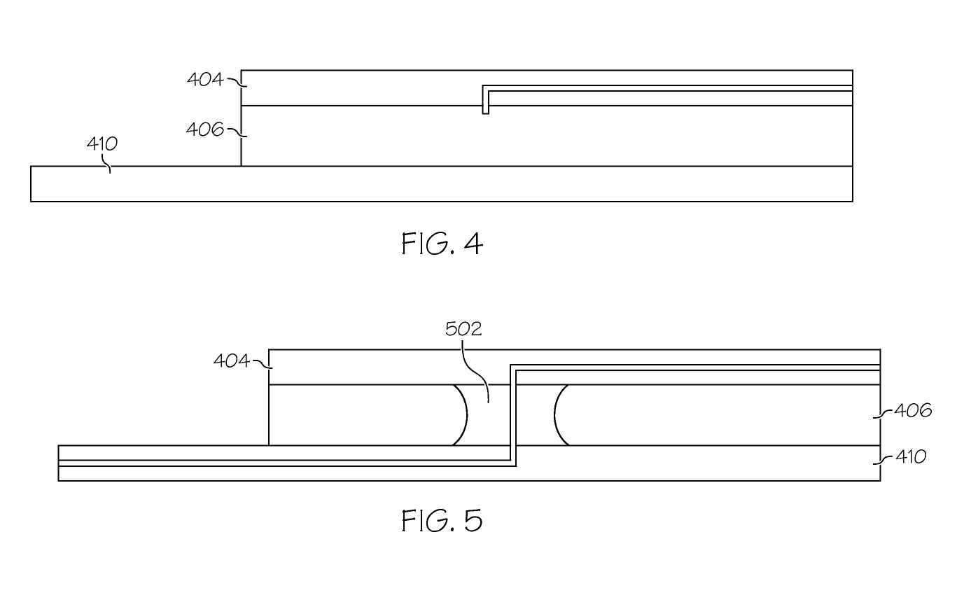

Referring now to FIG. 4, collar 404 (e.g., collar 304a shown in FIG. 3) is depicted as a metal layer that is adjacent to a non-conducting non-crystalline silicon (amorphous silicon ring) 406, such as amorphous silicon ring 306a shown in FIG. 3. Below the amorphous silicon ring 406 is another metal layer 410, shown as first capacitor plate 110a in FIGS. 1 and 3). As depicted in FIG. 4, the collar 404, and thus the voltage pin 116 shown in FIGS. 1 and 3, is initially insulated from the metal layer 410. However, if an antifuse 502 is grown by applying a voltage across the collar 404 and the metal plate 410, as shown in FIG. 5, then the collar 404 (e.g., collar 304a) and the voltage pin 116 are coupled to the metal plate 410 (first capacitor plate 110a), providing the voltage pin 116 with transient DC current provided by a charge on the first capacitor plate 110a. That is, by coupling the voltage pin 116 to the first capacitor plate 110a, surplus DC current from the voltage pin 116 will charge up the first capacitor plate 110a. This charge is thereafter available to the voltage pin 116 for short bursts of transient DC current. If the antifuses are grown within both amorphous silicon rings around the voltage pin 116, then both positive capacitor plates (110a and 110c shown in FIG. 3) are coupled to the voltage pin 116, resulting in the voltage pin 116 shown in FIG. 6 coupled to the positive capacitor plates 110a and 110c and having access to additional DC current.

In one embodiment of the present disclosure, the top surface area of the BGA adapter 102 is substantially the same size and shape as the bottom surface area of the module 104. Similarly, the decoupling capacitors 316a and/or 316b shown in FIG. 3 may extend to all edges of the BGA adapter 102, such that a single large decoupling capacitor provides decoupling capacitance to any power and/or ground pin for which the antifuse described herein has been grown to provide coupling to the respective capacitor plates.

Note that in one embodiment of the present disclosure, the antifuses described herein in the BGA adapter 102 are grown before the BGA adapter 102 is actually used to connect the module 104 to the circuit board 106. In one embodiment, some or all of the antifuses in the BGA adapter 102 are grown after connecting the module 104 to the circuit board 106. In either embodiment, the BGA module 104 is selectively programmable such that certain pins (e.g., power pins) in the module 104 are provided access to a positive capacitor plate while other pins (e.g., ground pins) in the module 104 are provided with additional sinking capacity from the negative capacitor plate.

With reference now to FIG. 7, additional detail is shown in another cross-section of the BGA module 102 shown in FIG. 3. Note that a voltage 702, which is of sufficient strength to create antifuses 502a-b for coupling the voltage pin 116 to the first voltage capacitor plate 110a. Voltage 702, or another voltage source (not shown) also creates/grows antifuses 502c-d in order to couple the voltage pin 116 to the second voltage capacitor plate 110c. A similar voltage source (not shown) is available to grow antifuses 502e-f, in order to couple the ground pin 118 to the first ground capacitor plate 110b, while another voltage source is available to grow antifuses 502g-h, in order to couple the ground pin 118 to the second ground capacitor plate 110d.

While FIG. 7 shows both of the capacitors 316a-b being coupled to the voltage pin 116 and the ground pin 118, in other embodiments only capacitor 316a or capacitor 316b is coupled to the voltage pin 116 and ground pin 118. By coupling capacitor 316a to the voltage pin 116 and the ground pin 118, inductance in the voltage pin 118 between the capacitor 316a and the module (shown in FIG. 3 as element 104) is kept to a minimum. Similarly, by coupling capacitor 316b to the voltage pin 116 and the ground pin 118, inductance in the ground pin 118 between the capacitor 316b and the mother board (shown in FIG. 3 as element 106) is kept to a minimum.

In one embodiment, all of the antifuses 502a-h shown in FIG. 7 can be grown at the same time. However, in another embodiment, antifuses are grown sequentially, in order to avoid a large pull of current from voltage 702. Thus, antifuse 502a can be grown, followed by antifuse 502b, followed by antifuse 502e, and then antifuse 502f, thus providing full connections between the voltage pin and the ground pin to capacitor 316a. Similarly, antifuse 502c can be grown, followed by antifuse 502d, followed by antifuse 502g, and then antifuse 502h, thus providing full connections between the voltage pin and the ground pin to capacitor 316b.

Note that programming a large number of antifuses 502 at the same time may produce unacceptable heating, during programming, in BGA adapter 102. For example, a BGA adapter 102 may have one hundred or more Vdd voltage pins 116 and a similar number of Gnd ground pins 118. As antifuses 502 are programmed, the antifuses 502 become low impedance conductors between a supply pin (e.g., Vdd voltage pin 116 or Gnd ground pin 118) and a capacitor plate (e.g., capacitor plate 110a) which is being coupled to the supply pin (e.g., Vdd voltage pin 116) by the programming voltage 702. Thus, to limit heating during programming and to reduce current requirements on voltage 702, programming can be done on a single supply pin at a time, or on a small number of supply pins at a time.

With reference now to FIG. 8, a cross section through voltage pin 116 showing a creation of an antifuse connection between the voltage pin 116 and the first voltage capacitor plate 110a is depicted without the use of a collar (shown in FIG. 7 as collar 304a). The collar 304a provides addition mechanical support to the fusion area (amorphous silicon ring 306a) shown in FIG. 7, but is not used in the embodiment depicted in FIG. 8.

With reference now to FIG. 9, a schematic 902 of FIGS. 3 and 7 is presented. As depicted, through the use of antifuses 502 and amorphous silicon rings 306a-b and 312a-b, decoupling capacitors 316a-b provide decoupling both to the voltage pin (Vdd) and the ground pin (Gnd). In another embodiment, different voltages can be decoupled by antifuses 502 and amorphous silicon rings 306a-b/312a-b through the independent and separated use of decoupling capacitors 316a and 316b, as depicted in schematic 1002 in FIG. 10.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of various embodiments of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described embodiments of the invention of the present application in detail and by reference to illustrative embodiments thereof, it will be apparent that modifications and variations are possible without departing from the scope of the invention defined in the appended claims.

What is claimed is:

1. An adapter for coupling a module to a circuit board, the adapter comprising:
a first decoupling capacitor within the adapter, wherein the first decoupling capacitor has a first capacitor plate and a second capacitor plate separated by an insulating dielectric;
a voltage pin and a ground pin traversing through the first decoupling capacitor;
a first fusible ring around the voltage pin, wherein the first fusible ring is adjacent to the first capacitor plate; and
a second fusible ring around the ground pin, wherein the second fusible ring is adjacent to the second capacitor plate.

2. The adapter of claim 1, wherein the first fusible ring is fused to the first capacitor plate by growing a first antifuse between the voltage pin and the first capacitor plate, and wherein the second fusible ring is fused to the second capacitor plate by growing a second antifuse between the ground pin and the second capacitor plate.

3. The adapter of claim 2, wherein the first fusible ring is fused by application of a sufficiently high voltage between the voltage pin and the first capacitor plate to electrically connect the voltage pin to the first capacitor plate.

4. The adapter of claim 2, wherein the second fusible ring is fused by application of a sufficiently high voltage between the ground pin and the second capacitor plate to electrically connect the ground pin to the second capacitor plate.

5. The adapter of claim 1, wherein the first decoupling capacitor extends to all edges of the adapter.

6. The adapter of claim 1, further comprising:
a second decoupling capacitor oriented below the first decoupling capacitor.

7. The adapter of claim 1, wherein the module and the adapter are coupled by a ball grid array (BGA).

8. The adapter of claim 1, further comprising:
a collar coupling the first fusible ring to the voltage pin.

9. A computer system comprising:
a circuit board;
a module; and
an adapter coupling the module to the circuit board, wherein the adapter comprises:
a first decoupling capacitor within the adapter, wherein the first decoupling capacitor has a first capacitor plate and a second capacitor plate separated by an insulating dielectric;
a voltage pin and a ground pin traversing through the first decoupling capacitor;
a first fusible ring around the voltage pin, wherein the first fusible ring is adjacent to the first capacitor plate; and
a second fusible ring around the ground pin, wherein the second fusible ring is adjacent to the second capacitor plate.

10. The computer system of claim 9, wherein the first fusible ring is fused to the first capacitor plate by growing a first antifuse between the voltage pin and the first capacitor plate, and wherein the second fusible ring is fused to the second capacitor plate by growing a second antifuse between the ground pin and the second capacitor plate.

11. The computer system of claim 10, wherein the first fusible ring is fused by application of a sufficiently high voltage between the voltage pin and the first capacitor plate to electrically connect the voltage pin to the first capacitor plate.

12. The computer system of claim 10, wherein the second fusible ring is fused by application of a sufficiently high voltage between the ground pin and the second capacitor plate to electrically connect the ground pin to the second capacitor plate.

13. The computer system of claim 9, wherein the first decoupling capacitor extends to all edges of the adapter.

14. The computer system of claim 9, wherein the adapter further comprises:
a second decoupling capacitor oriented below the first decoupling capacitor.

15. The computer system of claim 9, wherein the module and the adapter are coupled by a ball grid array (BGA).

16. The computer system of claim 9, wherein the adapter further comprises:
a collar coupling the first fusible ring to the voltage pin.
